(19) United States
(12) Patent Application Publication
(10) Pub. No.: US 2019/0198744 A1
(43) Pub. Date: Jun. 27, 2019

(54) HYBRID SOLAR AND SOLAR THERMAL DEVICE WITH EMBEDDED FLEXIBLE THIN-FILM BASED THERMOELECTRIC MODULE

(71) Applicant: Sridhar Kasichainula, Fremont, CA (US)

(72) Inventor: Sridhar Kasichainula, Fremont, CA (US)

(21) Appl. No.: 16/289,637

(22) Filed: Feb. 28, 2019

Related U.S. Application Data
(63) Continuation-in-part of application No. 15/808,902, filed on Nov. 10, 2017.
Application No. 15/808,902 is a continuation-in-part of application No. 14/564,072, filed on Dec. 8, 2014.
Application No. 15/808,902 is a continuation-in-part of application No. 14/711,810, filed on May 14, 2015, now Pat. No. 10,141,492.
Application No. 14/711,810 is a continuation-in-part of application No. 15/368,683, filed on Dec. 5, 2016, now Pat. No. 10,290,794.
(60) Provisional application No. 61/912,561, filed on Dec. 6, 2013.

(51) Int. Cl. H01L 35/34; H01L 31/18; H02S 10/30; H01L 35/02

(52) U.S. Cl. CPC H01L 35/34; H01L 35/02; H02S 10/30; H01L 31/186

(57) ABSTRACT

A method includes sputter depositing pairs of N-type and P-type thermoelectric legs electrically in contact with one another on a flexible substrate to form a thin-film based thermoelectric module, and rendering the formed thin-film based thermoelectric module flexible and less than or equal to 100 μm in dimensional thickness based on choices of fabrication processes with respect to layers thereof including the thermoelectric legs. The method also includes directly coupling the flexible thin-film based thermoelectric module to a layer of heat absorber material or a layer of photovoltaic material configured to receive sunlight to form the solar device, and leveraging a temperature difference across a first surface of the flexible thin-film based thermoelectric module directly in contact with the layer of heat absorber material or the layer of photovoltaic material and a second surface away therefrom to generate increased solar thermal power and/or electrical power output through the solar device.

### CLAIM OF PRIORITY

This application is a Continuation-in-Part application of co-pending U.S. application Ser. No. 15/808,902 titled FLEXIBLE THIN-FILM BASED THERMOELECTRIC DEVICE WITH SPUTTER DEPOSITED LAYER OF N-TYPE AND P-TYPE THERMOELECTRIC LEGS filed on Nov. 10, 2017, which is a Continuation-in-Part application of co-pending U.S. patent application Ser. No. 14/564,072 titled VOLTAGE GENERATION ACROSS TEMPERATURE DIFFERENTIALS THROUGH A THERMOELECTRIC LAYER COMPOSITE filed on Dec. 8, 2014, which is a conversion application of U.S. Provisional Application No. 61/912,561 also titled VOLTAGE GENERATION ACROSS TEMPERATURE DIFFERENTIALS THROUGH A THERMOELECTRIC LAYER COMPOSITE filed on Dec. 6, 2013, U.S. application Ser. No. 14/711,810 titled ENERGY HARVESTING FOR WEARABLE TECHNOLOGY THROUGH A THIN FLEXIBLE THERMOELECTRIC DEVICE filed on May 14, 2015 and issued as U.S. Pat. No. 10,141,492 on Nov. 27, 2018 and co-pending U.S. application Ser. No. 15/368,683 titled PIN COUPLING BASED THERMOELECTRIC DEVICE filed on Dec. 5, 2016. The content of the aforementioned applications are incorporated by reference in entirety thereof.

### FIELD OF TECHNOLOGY

This disclosure relates generally to thermoelectric devices and, more particularly, to a hybrid solar and a solar thermal device with embedded flexible thin-film based thermoelectric module.

### BACKGROUND

A solar device (e.g., a solar panel) may utilize a photovoltaic layer including solar cells to convert solar energy into electricity. Although photovoltaic based solar devices provide for scalability in use thereof, the aforementioned devices may be inefficient (e.g., efficiency ≤24%). Another solar device may be solar thermal based, leveraging heat energy of the sun. Although solar thermal installations may be relatively efficient, limitations in efficiency arising out of heat losses due to internal convection may prove to be a compromise therein.

### SUMMARY

Disclosed are methods, a device and/or a system of a hybrid solar and a solar thermal device with embedded flexible thin-film based thermoelectric module.

In one aspect, a method of a solar device includes sputter depositing pairs of N-type thermoelectric legs and P-type thermoelectric legs electrically in contact with one another on a flexible substrate to form a thin-film based thermoelectric module. The flexible substrate is aluminum (Al) foil, a sheet of paper, teflon, plastic, polyimide, a single-sided metal clad laminate, or a double-sided metal clad laminate. The method also includes rendering the formed thin-film based thermoelectric module flexible and less than or equal to 100 μm in dimensional thickness based on choices of fabrication processes with respect to layers of the formed thin-film based thermoelectric module including the sputter deposited N-type thermoelectric legs and the P-type thermoelectric legs.

Further, the method includes directly coupling the flexible thin-film based thermoelectric module to a layer of heat absorber material or a layer of photovoltaic material configured to receive sunlight such that the flexible thin-film based thermoelectric module is in contact therewith to form the solar device, and leveraging, through the directly coupled flexible thin-film based thermoelectric module, a temperature difference across a first surface of the flexible thin-film based thermoelectric module directly in contact with the layer of heat absorber material or the layer of photovoltaic material and a second surface away therefrom to generate increased solar thermal power and/or electrical power output through the solar device compared to an otherwise equivalent solar device without the formed thin-film based thermoelectric module.

In another aspect, a method of a solar device includes forming a flexible thin-film based thermoelectric module of less than or equal to 100 μm in dimensional thickness on a flexible substrate based on choices of fabrication processes and materials with respect to layers of the formed thin-film based thermoelectric module. The flexible substrate is an Al foil, a sheet of paper, teflon, plastic, polyimide, a single-sided metal clad laminate, or a double-sided metal clad laminate. The method also includes directly coupling the flexible thin-film based thermoelectric module to a layer of heat absorber material or a layer of photovoltaic material configured to receive sunlight such that the flexible thin-film based thermoelectric module is in contact therewith to form the solar device.

Further, the method includes leveraging, through the directly coupled flexible thin-film based thermoelectric module, a temperature difference across a first surface of the flexible thin-film based thermoelectric module directly in contact with the layer of heat absorber material or the layer of photovoltaic material and a second surface away therefrom to generate increased solar thermal power and/or electrical power output through the solar device compared to an otherwise equivalent solar device without the formed thin-film based thermoelectric module.

In yet another aspect, a method of a solar device includes forming a flexible thin-film based thermoelectric module of less than or equal to 100 μm in dimensional thickness on a flexible substrate based on choices of fabrication processes and materials with respect to layers of the formed thin-film based thermoelectric module. The flexible substrate is an Al foil, a sheet of paper, teflon, plastic, polyimide, a single-sided metal clad laminate, or a double-sided metal clad laminate. The method also includes directly coupling the flexible thin-film based thermoelectric module to a layer of heat absorber material or a layer of photovoltaic material configured to receive sunlight such that the flexible thin-film based thermoelectric module is in contact therewith to form the solar device.

Further, the method includes leveraging, through the directly coupled flexible thin-film based thermoelectric module, a temperature difference across a first surface of the flexible thin-film based thermoelectric module directly in contact with the layer of heat absorber material or the layer of photovoltaic material and a second surface away therefrom to generate increased solar thermal power and/or electrical power output through the solar device compared to an otherwise equivalent solar device without the formed thin-film based thermoelectric module while enabling retention of an outward physical appearance of the otherwise equivalent solar device.

Other features will be apparent from the accompanying drawings and from the detailed description that follows.

### BRIEF DESCRIPTION OF THE DRAWINGS

The embodiments of this invention are illustrated by way of example and not limitation in the figures of the accompanying drawings, in which like references indicate similar elements and in which:

FIG. 1 is a schematic view of a thermoelectric device.

FIG. 2 is a schematic view of an example thermoelectric device with alternating P and N elements.

FIG. 3 is a top schematic view of a thermoelectric device component, according to one or more embodiments.

FIG. 4 is a process flow diagram detailing the operations involved in realizing a patterned flexible substrate of a thermoelectric device as per a design pattern, according to one or more embodiments.

FIG. 5 is a schematic view of the patterned flexible substrate of FIG. 4, according to one or more embodiments.

FIG. 6 is a schematic view of the patterned flexible substrate of FIG. 4 with N-type thermoelectric legs, P-type thermoelectric legs, a barrier layer and conductive interconnects, according to one or more embodiments.

FIG. 7 is a process flow diagram detailing the operations involved in sputter deposition of the N-type thermoelectric legs of FIG. 6 on the patterned flexible substrate (or, a seed metal layer) of FIG. 5, according to one or more embodiments.

FIG. 8 is a process flow diagram detailing the operations involved in deposition of the barrier layer of FIG. 6 on top of the sputter deposited pairs of P-type thermoelectric legs and the N-type thermoelectric legs of FIG. 6 and forming the conductive interconnects of FIG. 6 on top of the barrier layer, according to one or more embodiments.

FIG. 9 is a process flow diagram detailing the operations involved in encapsulating the thermoelectric device of FIG. 4 and FIG. 6, according to one or more embodiments.

FIG. 10 is a schematic view of a flexible thermoelectric device embedded within a watch strap of a watch completely wrappable around a wrist of a human being.

FIG. 11 is a schematic view of a flexible thermoelectric device wrapped around a heat pipe.

FIG. 12 is schematic view of a solar device, according to one or more embodiments.

FIG. 13 is a schematic view of another solar device, according to one or more embodiments.

FIG. 14 is a schematic view of yet another solar device, according to one or more embodiments.

FIG. 15 is a schematic view of still yet another solar device, according to one or more embodiments.

FIG. 16 is a process flow diagram detailing the operations involved in realizing the solar devices of FIGS. 12-15, according to one or more embodiments.

Other features of the present embodiments will be apparent from the accompanying drawings and from the detailed description that follows.

### DETAILED DESCRIPTION

Example embodiments, as described below, may be used to provide methods, a device and/or a system of a hybrid solar and a solar thermal device with embedded flexible thin-film based thermoelectric module. Although the present embodiments have been described with reference to specific example embodiments, it will be evident that various modifications and changes may be made to these embodiments without departing from the broader spirit and scope of the various embodiments.

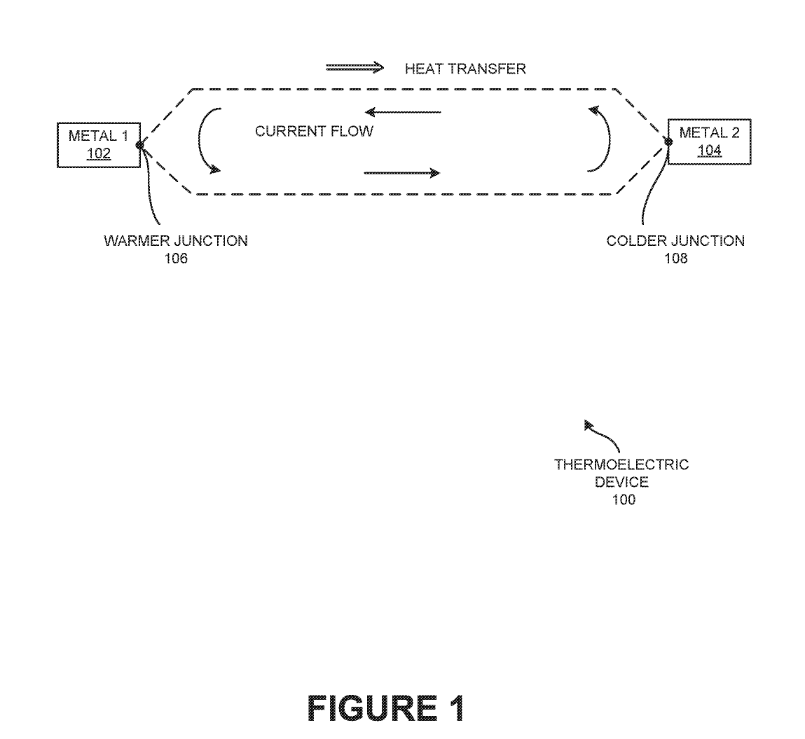

FIG. 1 shows a thermoelectric device 100. Thermoelectric device 100 may include different metals, metal 1 102 and metal 2 104, forming a closed circuit. Here, a temperature difference between junctions of said dissimilar metals leads to energy levels of electrons therein shifted in a dissimilar manner. This results in a potential/voltage difference between the warmer (e.g., warmer junction 106) of the junctions and the colder (e.g., colder junction 108) of the junctions. The aforementioned conversion of heat into electricity at junctions of dissimilar metals is known as Seebeck effect.

The most common thermoelectric devices in the market may utilize alternative P and N type legs/pellets/elements made of semiconducting materials. As heat is applied to one end of a thermoelectric device based on P and N type elements, charge carriers thereof may be released into the conduction band. Electron (charge carrier) flow in the N type element may contribute to a current flowing from the end (hot end) where the heat is applied to the other end (cold end). Hole (charge carrier) flow in the P type element may contribute to a current flowing from the other end (cold end) to the end (hot end) where the heat is applied. Here, heat may be removed from the cold end to prevent equalization of charge carrier distribution in the semiconductor materials due to migration thereof.

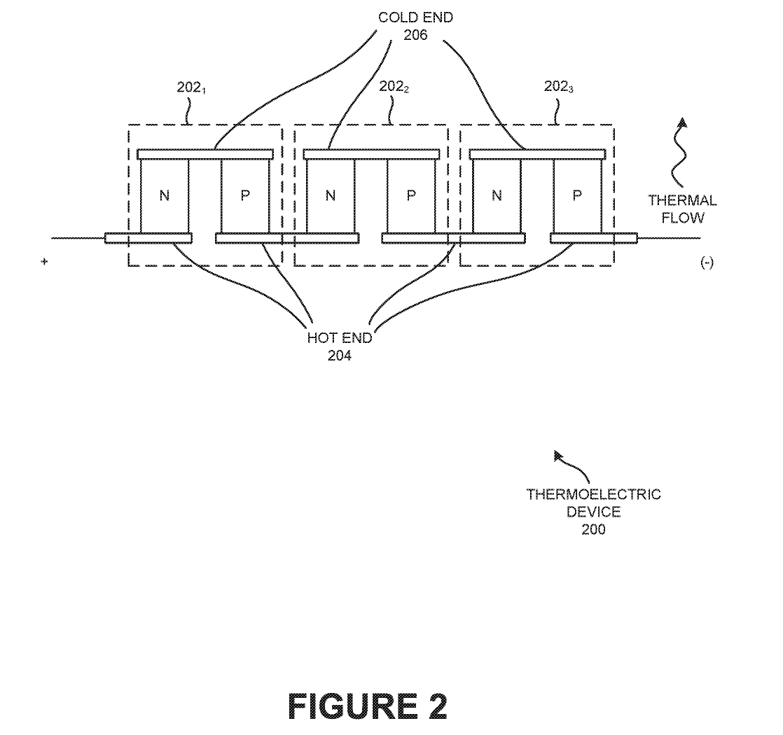

In order to generate voltage at a meaningful level to facilitate one or more application(s), typical thermoelectric devices may utilize alternating P and N type elements (legs/pellets) electrically coupled in series (and thermally coupled in parallel) with one another, as shown in FIG. 2. FIG. 2 shows an example thermoelectric device 200 including three alternating P and N type elements 202₁₋₃. The hot end (e.g., hot end 204) where heat is applied and the cold end (e.g., cold end 206) are also shown in FIG. 2.

Typical thermoelectric devices (e.g., thermoelectric device 200) may be limited in application thereof because of rigidity, bulkiness and high costs (>$20/watt) associated therewith. Also, these devices may operate at high temperatures using active cooling. Exemplary embodiments discussed herein provide for a thermoelectric platform (e.g., enabled via roll-to-roll sputtering on a flexible substrate (e.g., plastic)) that offers a large scale, commercially viable, high performance, easy integration and inexpensive (<20 cents/watt) route to flexible thermoelectrics.

In accordance with the exemplary embodiments, P and N thermoelectric legs may be deposited on a flexible substrate (e.g., plastic) using a roll-to-roll process that offers scalability and cost savings associated with the N and P materials. In a typical solution, bulk legs may have a height in millimeters (mm) and an area in mm². In contrast, N and P bulk legs described in the exemplary embodiments discussed herein may have a height in microns (μm) and an area in the μm² to mm² range.

Examples of flexible substrates may include but are not limited to aluminum (Al) foil, a sheet of paper, teflon, plastic, polyimide and a single/double-sided metal (e.g., copper (Cu)) clad laminate. As will be discussed below, exemplary embodiments involve processes for manufacturing/fabrication of thermoelectric devices/modules that enable flexibility thereof not only in terms of substrates but also in terms of thin films/thermoelectric legs/interconnects/packaging. Preferably, exemplary embodiments provide for thermoelectric devices/modules completely wrappable and bendable around other devices utilized in specific applications, as will be discussed below. Further, exemplary embodiments provide for manufactured/fabricated thermoelectric devices/modules that are each less than or equal to 100 μm in dimensional thickness.

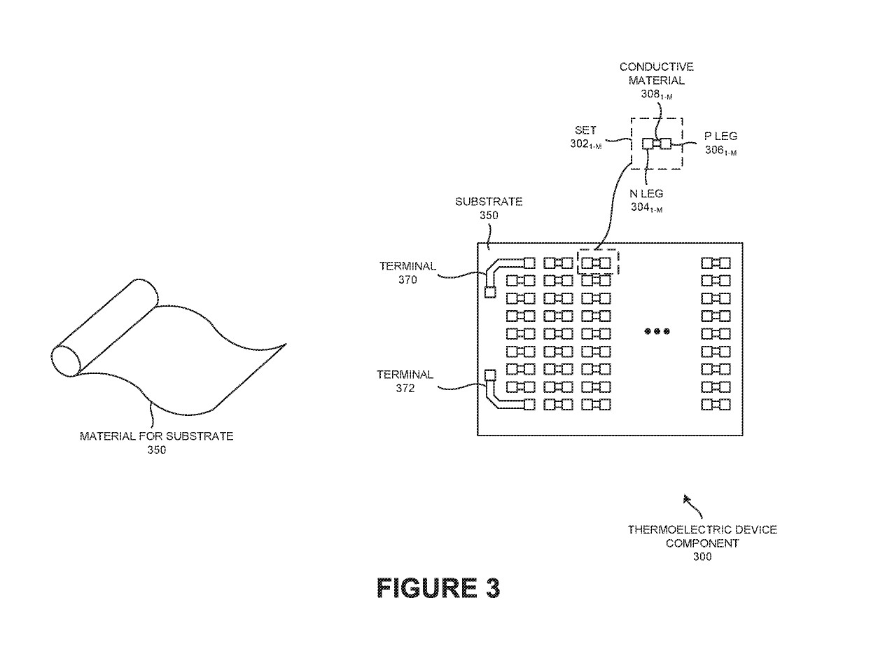

FIG. 3 shows a top view of a thermoelectric device component 300, according to one or more embodiments. Here, in one or more embodiments, a number of sets of N and P legs (e.g., sets 302_{1-M} including N legs 304_{1-M} and P legs 306_{1-M} therein) may be deposited on a substrate 350 (e.g., plastic, metal clad laminate) using a roll-to-roll process discussed above. FIG. 3 also shows a conductive material 308_{1-M} contacting both a set 302_{1-M} and substrate 350, according to one or more embodiments; an N leg 304_{1-M} and a P leg 306_{1-M} form a set 302_{1-M}, in which N leg 304_{1-M} and P leg 306_{1-M} electrically contact each other through conductive material 308_{1-M}. Terminals 370 and 372 may be electrically conductive leads to measure the potential difference generated by a thermoelectric device including thermoelectric device component 300.

Exemplary thermoelectric devices discussed herein may find utility in solar and solar thermal applications. As discussed above, traditional thermoelectric devices may have a size limitation and may not scale to a larger area. For example, a typical solar panel may have an area in the square meter (m²) range and the traditional thermoelectric device may have an area in the square inch range. A thermoelectric device in accordance with the exemplary embodiments may be of varying sizes and/or dimensions ranging from a few mm² to a few m².

Additionally, exemplary thermoelectric devices may find use in low temperature applications such as harvesting body heat in a wearable device, automotive devices/components and Internet of Things (IoT). Entities (e.g., companies, start-ups, individuals, conglomerates) may possess expertise to design and/or develop devices that require thermoelectric modules, but may not possess expertise in the fabrication and packaging of said thermoelectric modules. Alternately, even though the entities may possess the requisite expertise in the fabrication and packaging of the thermoelectric modules, the entities may not possess a comparative advantage with respect to the aforementioned processes.

In one scenario, an entity may create or possess a design pattern for a thermoelectric device. Said design pattern may be communicated to another entity associated with a thermoelectric platform to be tangibly realized as a thermoelectric device. It could also be envisioned that the another entity may provide training with regard to the fabrication processes to the one entity or outsource aspects of the fabrication processes to a third-party. Further, the entire set of processes involving Intellectual Property (IP) generation and manufacturing/fabrication of the thermoelectric device may be handled by a single entity. Last but not the least, the entity may generate the IP involving manufacturing/fabrication of the thermoelectric device and outsource the actual manufacturing/fabrication processes to the another entity.

All possible combinations of entities and third-parties are within the scope of the exemplary embodiments discussed herein.

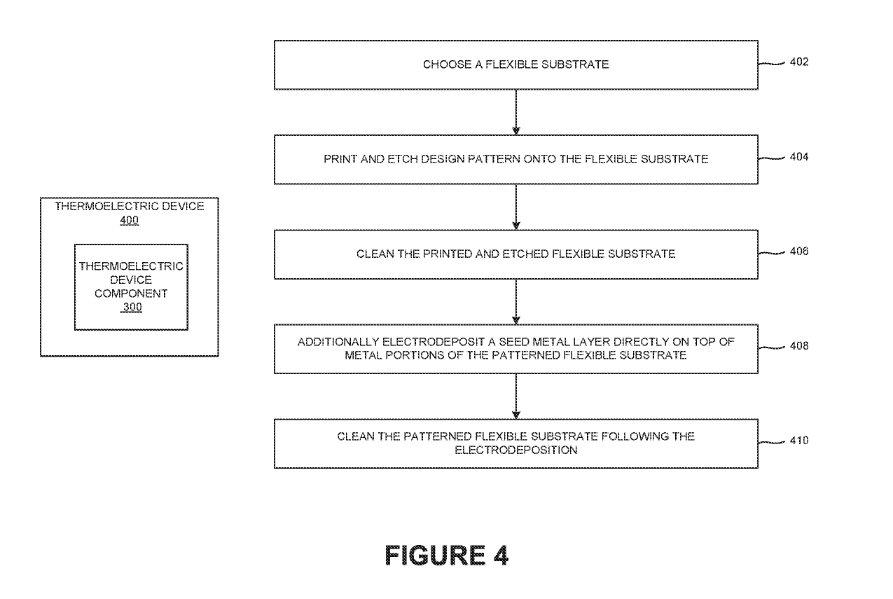

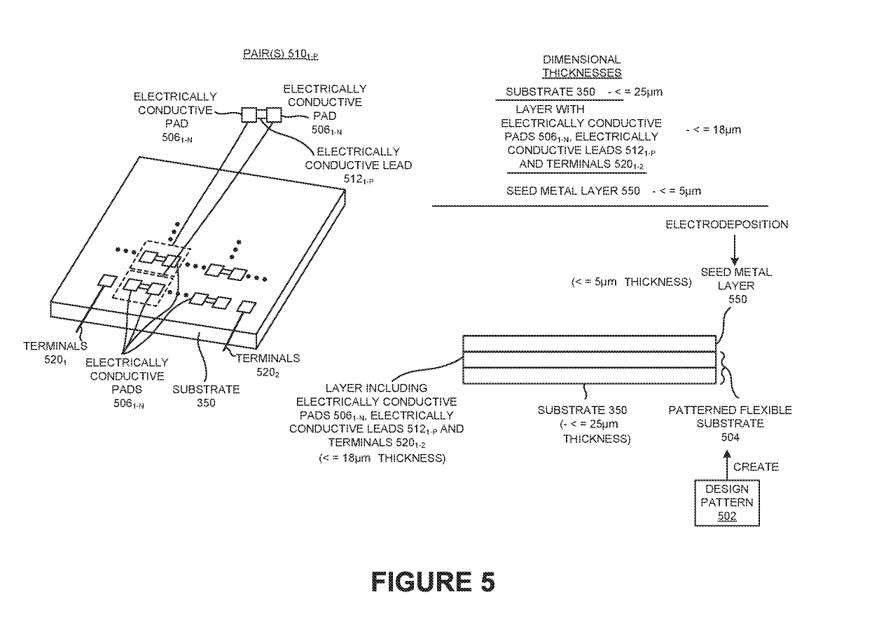

FIG. 4 shows the operations involved in realizing a patterned flexible substrate (e.g., patterned flexible substrate 504 shown in FIG. 5) of a thermoelectric device 400 as per a design pattern (e.g., design pattern 502 shown in FIG. 5), according to one or more embodiments. In one or more embodiments, operation 402 may involve choosing a flexible substrate (e.g., substrate 350) onto which, in operation 404, design pattern 502 may be printed (e.g., through inkjet printing, direct write, screen printing) and etched onto the flexible substrate. In one or more embodiments, a dimensional thickness of substrate 350 may be less than or equal to 25 μm.

Etching, as defined above, may refer to the process of removing (e.g., chemically) unwanted metal (say, Cu) from the patterned flexible substrate. In one example embodiment, a mask (e.g., a shadow mask) or a resist may be placed on portions of the patterned flexible substrate corresponding to portions of the metal that are to remain after the etch. Here, in one or more embodiments, the portions of the metal that remain on the patterned flexible substrate may be electrically conductive pads, electrically conductive leads and terminals formed on a surface of the patterned flexible substrate. FIG. 5 shows a patterned flexible substrate 504 including a number of electrically conductive pads 506_{1-N} formed thereon. Each electrically conductive pad 506_{1-N} may be a flat area of the metal that enables an electrical connection.

Also, FIG. 5 shows a majority set of the electrically conductive pads 506_{1-N} as including pairs 510_{1-P} of electrically conductive pads 506_{1-N} in which one electrically conductive pad 506_{1-N} may be electrically paired to another electrically conductive pad 506_{1-N} through an electrically conductive lead 512_{1-P} also formed on patterned flexible substrate 504; terminals 520₁₋₂ (e.g., analogous to terminals 370 and 372) may also be electrically conductive leads to measure the potential difference generated by the thermoelectric device/module fabricated based on design pattern 502. The aforementioned potential difference may be generated based on heat (or, cold) applied at an end of the thermoelectric device/module.

It should be noted that the configurations of the electrically conductive pads 506_{1-N}, electrically conductive leads 512_{1-P} and terminals 520₁₋₂ shown in FIG. 5 are merely for example purposes, and that other example configurations are within the scope of the exemplary embodiments discussed herein. It should also be noted that patterned flexible substrate 504 may be formed based on design pattern 502 in accordance with the printing and etching discussed above.

Example etching solutions employed may include but are not limited to ferric chloride and ammonium persulphate. Referring back to FIG. 4, operation 406 may involve cleaning the printed and etched flexible substrate. For example, acetone, hydrogen peroxide or alcohol may be employed therefor. Other forms of cleaning are within the scope of the exemplary embodiments discussed herein. In one or more embodiments, the aforementioned processes discussed in FIG. 4 may result in a dimensional thickness of electrically conductive pads 506_{1-N}, electrically conductive leads 512_{1-P} and terminals 520₁₋₂ being less than or equal to 18 μm.

The metal (e.g., Cu) finishes on the surface of patterned flexible substrate 504 may oxidize over time if left unprotected. As a result, in one or embodiments, operation 408 may involve additionally electrodepositing a seed metal layer 550 including Chromium (Cr), Nickel (Ni) and/or Gold (Au) directly on top of the metal portions (e.g., electrically conductive pads 506_{1-N}, electrically conductive leads 512_{1-P}, terminals 520₁₋₂) of patterned flexible substrate 504 following the printing, etching and cleaning. In one or more embodiments, a dimensional thickness of seed metal layer 550 may be less than or equal to 5 μm.

In one example embodiment, surface finishing may be employed to electrodeposit seed metal layer 550; the aforementioned surface finishing may involve Electroless Nickel Immersion Gold (ENIG) finishing. Here, a coating of two layers of metal may be provided over the metal (e.g., Cu) portions of patterned flexible substrate 504 by way of Au being plated over Ni. Ni may be the barrier layer between Cu and Au. Au may protect Ni from oxidization and may provide for low contact resistance. Other forms of surface finishing/electrodeposition may be within the scope of the exemplary embodiments discussed herein. It should be noted that seed metal layer 550 may facilitate contact of sputter deposited N-type thermoelectric legs (to be discussed below) and P-type thermoelectric legs (to be discussed below) thereto.

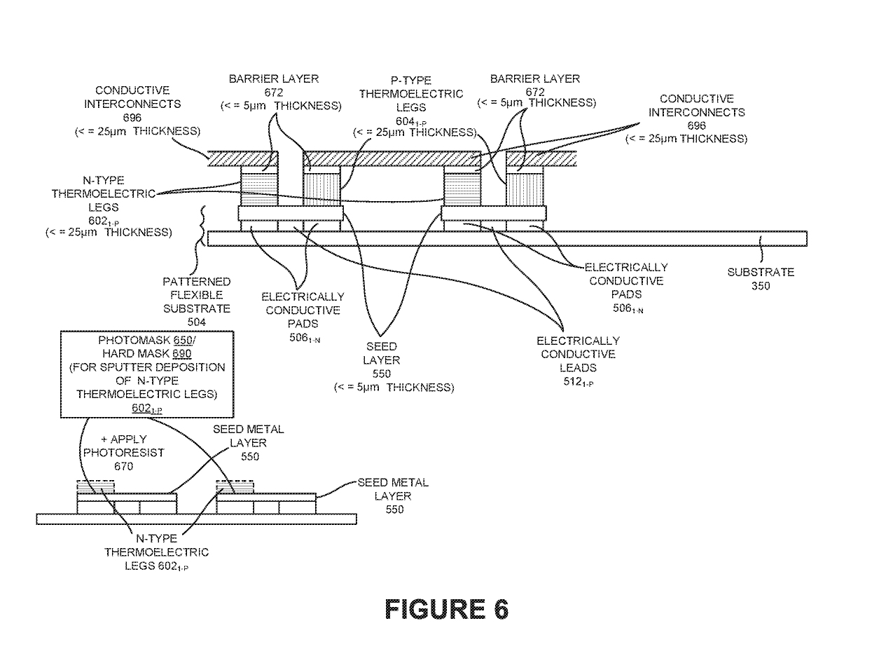

In one or more embodiments, operation 410 may then involve cleaning patterned flexible substrate 504 following the electrodeposition. FIG. 6 shows an N-type thermoelectric leg 602_{1-P} and a P-type thermoelectric leg 604_{1-P} formed on each pair 510_{1-P} of electrically conductive pads 506_{1-N}, according to one or more embodiments. In one or more embodiments, the aforementioned N-type thermoelectric legs 602_{1-P} and P-type thermoelectric legs 604_{1-P} may be formed on the surface finished patterned flexible substrate 504 (note: in FIG. 6, seed layer 550 is shown as surface finishing over electrically conductive pads 506_{1-N}/leads 512_{1-P}; terminals 520₁₋₂ have been omitted for the sake of clarity) of FIG. 5 through sputter deposition.

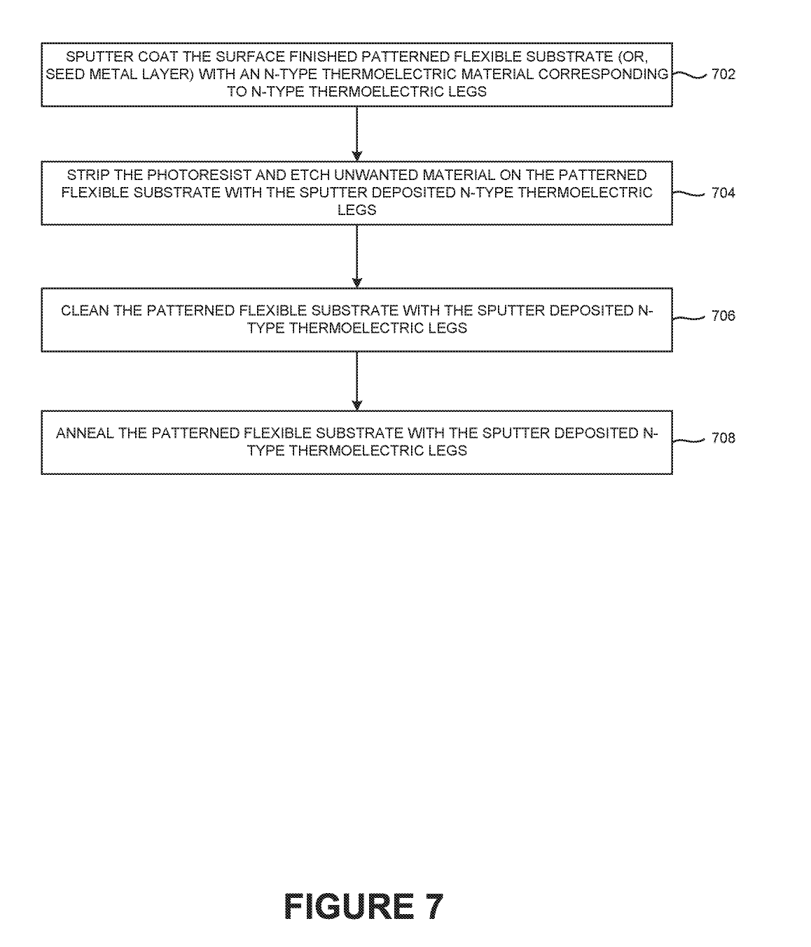

FIG. 7 details the operations involved in sputter deposition of N-type thermoelectric legs 602_{1-P} on the surface finished patterned flexible substrate 504 (or, seed metal layer 550) of FIG. 5, according to one or more embodiments. In one or more embodiments, the aforementioned process may involve a photomask 650 (shown in FIG. 6) on which patterns corresponding/complementary to the N-type thermoelectric legs 602_{1-P} may be generated. In one or more embodiments, a photoresist 670 (shown in FIG. 6) may be applied on the surface finished patterned flexible substrate 504, and photomask 650 placed thereon. In one or more embodiments, operation 702 may involve sputter coating (e.g., through magnetron sputtering) of the surface finished patterned flexible substrate 504 (or, seed metal layer 550) with an N-type thermoelectric material corresponding to N-type thermoelectric legs 602_{1-P}, aided by the use of photomask 650. The photoresist 670/photomask 650 functions are well understood to one skilled in the art; detailed discussion associated therewith has been skipped for the sake of convenience and brevity.

In one or more embodiments, operation 704 may involve stripping (e.g., using solvents such as dimethyl sulfoxide or alkaline solutions) of photoresist 670 and etching of unwanted material on patterned flexible substrate 504 with sputter deposited N-type thermoelectric legs 602_{1-P}. In one or more embodiments, operation 706 may involve cleaning the patterned flexible substrate 504 with the sputter deposited N-type thermoelectric legs 602_{1-P}; the cleaning process may be similar to the discussion with regard to FIG. 4.

In one or more embodiments, operation 708 may then involve annealing the patterned flexible substrate 504 with the sputter deposited N-type thermoelectric legs 602_{1-P}; the annealing process may be conducted (e.g., in air or vacuum) at 175° C. for 4 hours. In one or more embodiments, the annealing process may remove internal stresses and may contribute stability of the sputter deposited N-type thermoelectric legs 602_{1-P}. In one or more embodiments, a dimensional thickness of the sputter deposited N-type thermoelectric legs 602_{1-P} may be less than or equal to 25 μm.

It should be noted that P-type thermoelectric legs 604_{1-P} may also be sputter deposited on the surface finished pattern flexible substrate 504. The operations associated therewith are analogous to those related to the sputter deposition of N-type thermoelectric legs 602_{1-P}. Obviously, photomask 650 may have patterns corresponding/complementary to the P-type thermoelectric legs 604_{1-P} generated thereon. Detailed discussion associated with the sputter deposition of P-type thermoelectric legs 604_{1-P} has been skipped for the sake of convenience; it should be noted that a dimensional thickness of the sputter deposited P-type thermoelectric legs 604_{1-P} may also be less than or equal to 25 μm.

It should be noted that the sputter deposition of P-type thermoelectric legs 604_{1-P} on the surface finished patterned flexible substrate 504 may be performed after the sputter deposition of N-type thermoelectric legs 602_{1-P} thereon or vice versa. Also, it should be noted that various feasible forms of sputter deposition are within the scope of the exemplary embodiments discussed herein. In one or more embodiments, the sputter deposited P-type thermoelectric legs 604_{1-P} and/or N-type thermoelectric legs 602_{1-P} may include a material chosen from one of: Bismuth Telluride (Bi₂Te₃), Bismuth Selenide (Bi₂Se₃), Antimony Telluride (Sb₂Te₃), Lead Telluride (PbTe), Silicides, Skutterudites and Oxides.

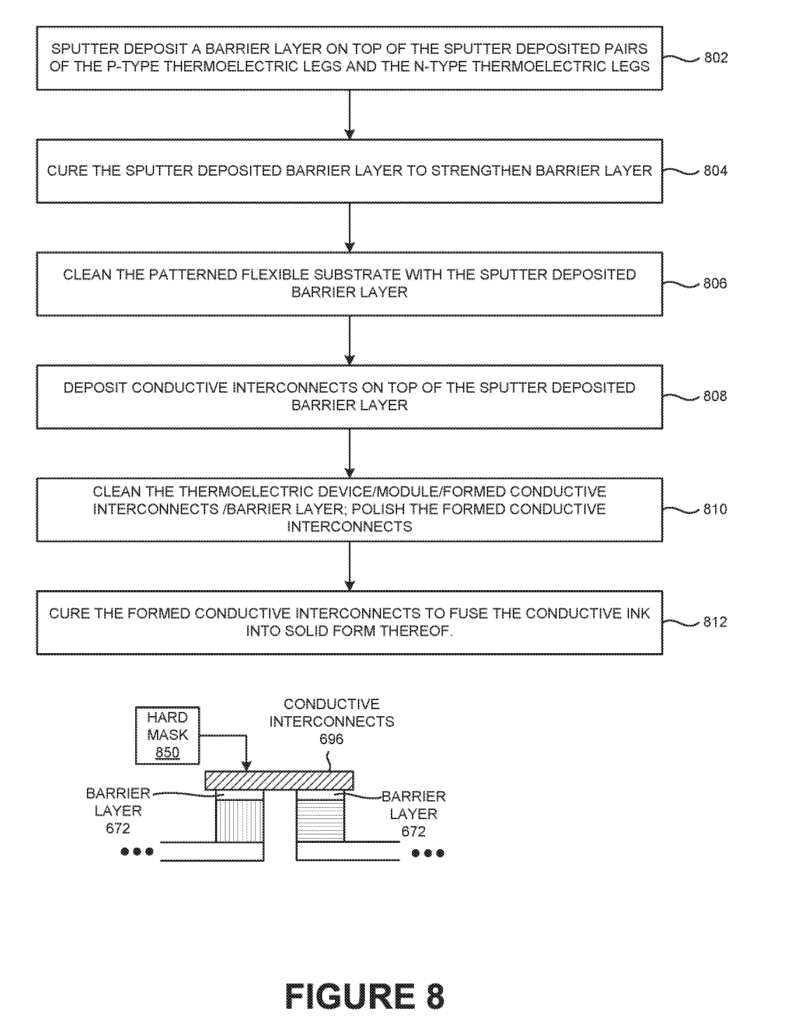

FIG. 8 details operations involved in deposition of a barrier layer 672 (refer to FIG. 6) on top of the sputter deposited pairs of P-type thermoelectric legs 604_{1-P} and N-type thermoelectric legs 602_{1-P} and forming conductive interconnects 696 on top of barrier layer 672, according to one or more embodiments.

In one or more embodiments, operation 802 may involve sputter depositing barrier layer 672 (e.g., film) on top of the sputter deposited pairs of the P-type thermoelectric legs 604_{1-P} and the N-type thermoelectric leg 602_{1-P} discussed above. In one or more embodiments, barrier layer 672 may be electrically conductive and may have a higher melting temperature than the thermoelectric material forming the P-type thermoelectric legs 604_{1-P} and the N-type thermoelectric legs 602_{1-P}. In one or more embodiments, barrier layer 672 may prevent corruption (e.g., through diffusion, sublimation) of one layer (e.g., the thermoelectric layer including the P-type thermoelectric legs 604_{1-P} and the N-type thermoelectric legs 602_{1-P}) by another layer. An example material employed as barrier layer 672 may include but is not limited to Cr, Ni or Au. Further, in one or more embodiments, barrier layer 672 may further aid metallization contact therewith (e.g., with conductive interconnects 696).

In one or more embodiments, a dimensional thickness of barrier layer 672 may be less than or equal to 5 μm. It is obvious that another photomask (not shown) analogous to photomask 650 may be employed to aid the patterned sputter deposition of barrier layer 672; details thereof have been skipped for the sake of convenience and clarity. In one or more embodiments, operation 804 may involve may involve curing barrier layer 672 at 175° C. for 4 hours to strengthen barrier layer 672. In one or more embodiments, operation 806 may then involve cleaning patterned flexible substrate 504 with barrier layer 672.

In one or more embodiments, operation 808 may involve depositing conductive interconnects 696 on top of barrier layer 672. In one example embodiment, the aforementioned deposition may be accomplished by screen printing silver (Ag) ink or other conductive forms of ink on barrier layer 672. Other forms of conductive interconnects 696 based on conductive paste(s) are within the scope of the exemplary embodiments discussed herein. As shown in FIG. 8, a hard mask 850 may be employed to assist the selective application of conductive interconnects 696 based on screen printing of Ag ink. In one example embodiment, hard mask 850 may be a stencil.

In one or more embodiments, the screen printing of Ag ink may contribute to the continued flexibility of the thermoelectric device/module and low contact resistance. In one or more embodiments, operation 810 may involve cleaning (e.g., using one or more of the processes discussed above) the thermoelectric device/module/formed conductive interconnects 696/barrier layer 672 and polishing conductive interconnects 696. In one example embodiment, the polishing may be followed by another cleaning process. In one or more embodiments, operation 812 may then involve curing conductive interconnects 696 at 175° C. for 4 hours to fuse the conductive ink into solid form thereof. In one or more embodiments, conductive interconnects 696 may have a dimensional thickness less than or equal to 25 μm.

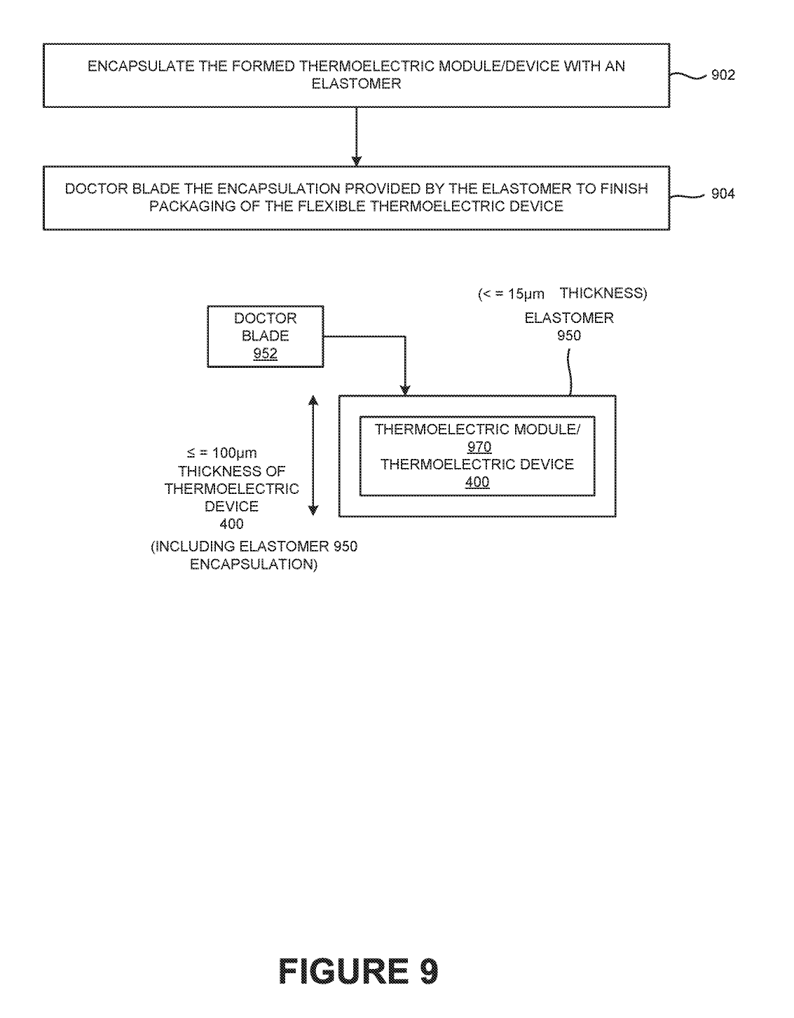

FIG. 9 details the operations involved in encapsulating the thermoelectric device (e.g., thermoelectric module 970)/module discussed above, according to one or more embodiments. In one or more embodiments, operation 902 may involve encapsulating the formed thermoelectric module (e.g., thermoelectric module 970)/device (with barrier layer 672 and conductive interconnects 696) with an elastomer 950 to render flexibility thereto. In one or more embodiments, as shown in FIG. 9, the encapsulation provided by elastomer 950 may have a dimensional thickness of less than or equal to 15 μm. In one or more embodiments, operation 904 may involve doctor blading (e.g., using doctor blade 952) the encapsulation provided by elastomer 950 to finish packaging of the flexible thermoelectric device/module discussed above.

In one or more embodiments, the doctor blading may involve controlling precision of a thickness of the encapsulation provided by elastomer 950 through doctor blade 952. In one example embodiment, elastomer 950 may be silicone. Here, said silicone may be loaded with nano-size aluminum oxide (Al₂O₃) powder to enhance thermal conductivity thereof to aid heat transfer across the thermoelectric module.

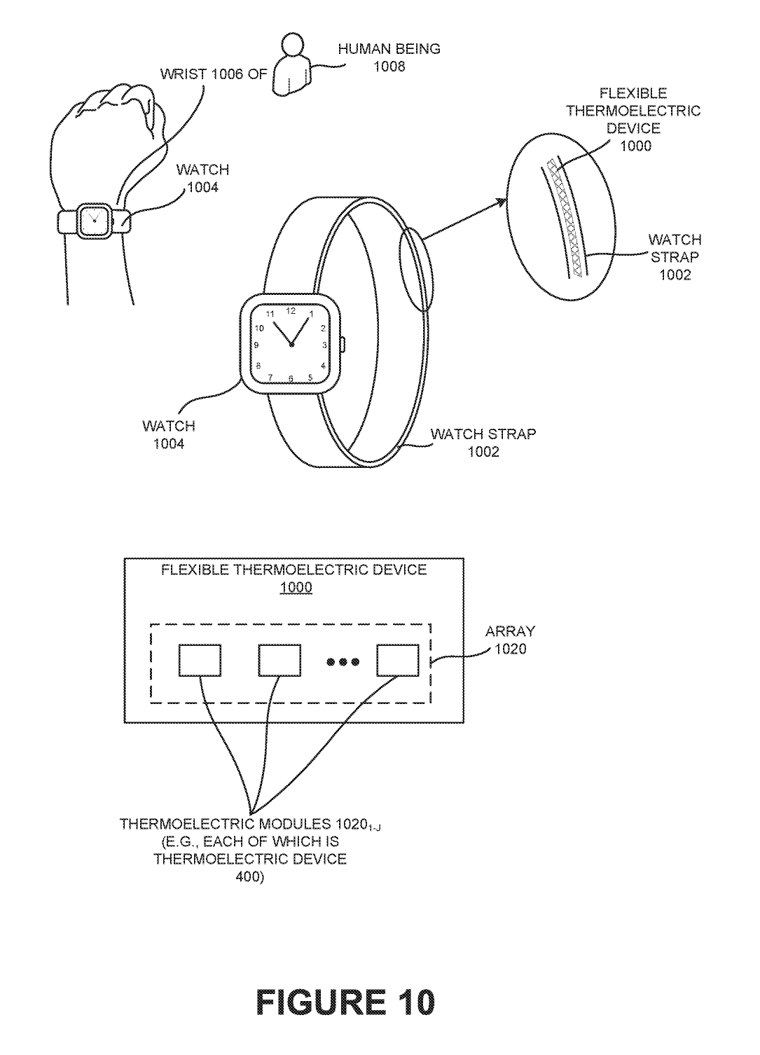

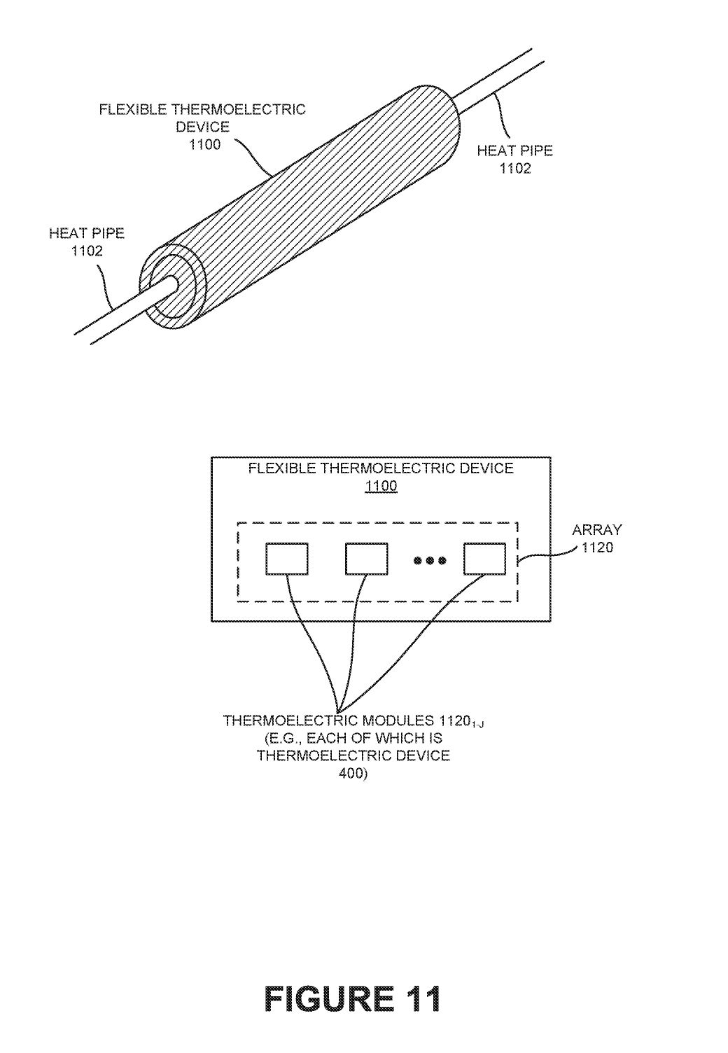

In one or more embodiments, as seen above, all operations involved in fabricating the thermoelectric device/module (e.g., thermoelectric device 400) render said thermoelectric device/module flexible. FIG. 10 shows a flexible thermoelectric device 1000 discussed herein embedded within a watch strap 1002 of a watch 1004 completely wrappable around a wrist 1006 of a human being 1008; flexible thermoelectric device 1000 may include an array 1020 of thermoelectric modules 1020_{1-J} (e.g., each of which is thermoelectric device 400) discussed herein. In one example embodiment, flexible thermoelectric device 1000 may serve to augment or substitute power derivation from a battery of watch 1004. FIG. 11 shows a flexible thermoelectric device 1100 discussed herein wrapped around a heat pipe 1102; again, flexible thermoelectric device 1100 may include an array 1120 of thermoelectric modules 1120_{1-J} (e.g., each of which is thermoelectric device 400) discussed herein. In one example embodiment, flexible thermoelectric device 1100 may be employed to derive thermoelectric power (e.g., through array 1120) from waste heat from heat pipe 1102.

It should be noted that although photomask 650 is discussed above with regard to deposition of N-type thermoelectric legs 602_{1-P} and a P-type thermoelectric legs 604_{1-P}, the aforementioned deposition may, in one or more other embodiments, involve a hard mask 690, as shown in FIG. 6. Further, it should be noted that flexible thermoelectric device 400/1000/1100 may be fabricated/manufactured such that the aforementioned device is completely wrappable and bendable around a system element (e.g., watch 1004, heat pipe 1102) that requires said flexible thermoelectric device 400/1000/1100 to perform a thermoelectric power generation function using the system element.

The abovementioned flexibility of thermoelectric device 400/1000/1100 may be enabled through proper selection of flexible substrates (e.g., substrate 350) and manufacturing techniques/processes that aid therein, as discussed above. Further, flexible thermoelectric device 1000/1100 may be bendable 360° such that the entire device may completely wrap around the system element discussed above. Still further, in one or more embodiments, an entire dimensional thickness of the flexible thermoelectric module (e.g., flexible thermoelectric device 400) in a packaged form may be less than or equal to 100 μm, as shown in FIG. 9.

Last but not the least, as the dimensions involved herein are restricted to less than or equal to 100 μm, the flexible thermoelectric device/module discussed above may be regarded as being thin-film based (e.g., including processes involved in fabrication thereof).

In one or more embodiments, thermoelectric device 400/thermoelectric module 970 may be easily amenable to use in solar devices such as solar panels/flat plate collectors. Solar thermal installations may harvest the heat energy of the sun. The heat then may be used to drive other mechanical systems for power production. One or more embodiments discussed herein may relate to integrating thermoelectric device 400/thermoelectric module 970 with solar devices such as a solar panel.

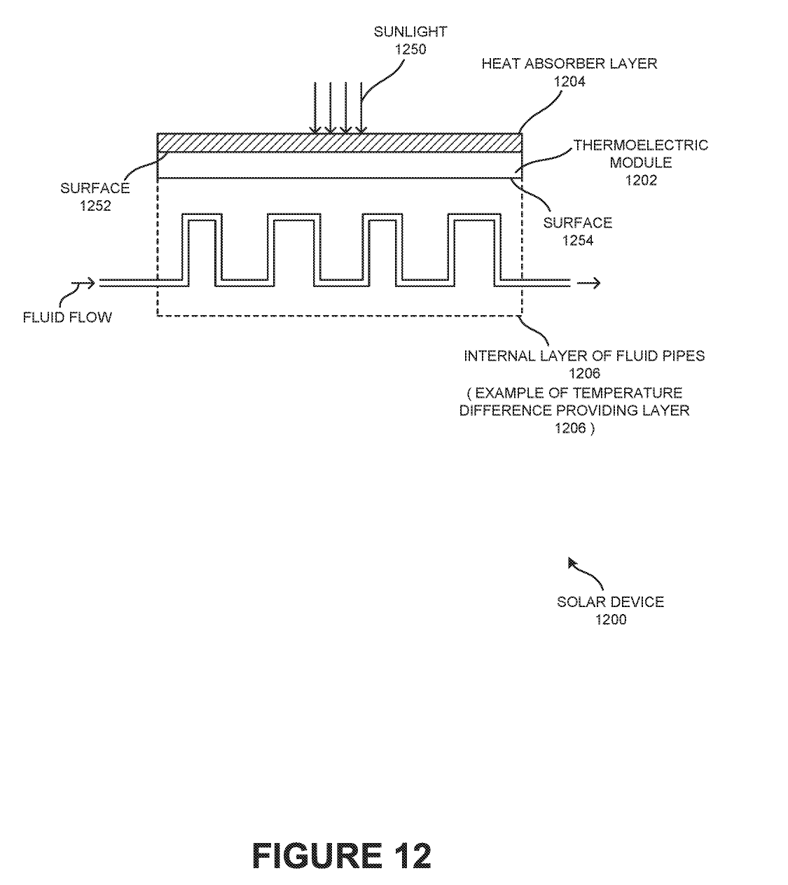

FIG. 12 shows a solar device 1200 (e.g., a solar panel), according to one or more embodiments. In one or more embodiments, solar device 1200 may include a thermoelectric module 1202 (e.g., thermoelectric module 970, embodiments of FIGS. 3-8) in a lightweight, paper thin form coupled to (e.g., placed right below) a heat absorber layer 1204 and in contact therewith; one surface 1252 (e.g., a top surface) of thermoelectric module 1202 may directly contact heat absorber layer 1204. In one or more embodiments, another surface 1254 (e.g., a bottom surface) of thermoelectric module 1202 may contact an internal layer of fluid pipes 1206 (e.g., cold enough to provide for a temperature difference across surface 1252 and surface 1254; the fluid pipes may provide for cooling by way of carrying air or a fluid such as water; in certain cases, internal layer of fluid pipes 1206 may be at ambient temperature), as shown in FIG. 12. As a temperature difference between surface 1252 and surface 1254 of thermoelectric module 1202 generates a potential difference and, therefore, current, in one or more embodiments, the temperature difference between heat absorber layer 1204 and internal layer of fluid pipes 1206 may be utilized to generate electric power.

In one example embodiment, heat absorber layer 1204 may include a metallic material (e.g., Copper, Aluminum) coated with a special material such as TiNOX to efficiently absorb incident solar light energy (e.g., sunlight 1250) and effect transformation thereof into heat/thermal energy, thereby resulting in minimal reflection and radiation losses. It should be noted that surface 1254, in one or more other embodiments, may be in contact with a layer that provides for a temperature difference between surface 1252 and surface 1254. In other words, any layer that provides for a temperature difference between surface 1252 and surface 1254 may substitute internal layer of fluid pipes 1206. FIG. 12 shows a temperature difference providing layer 1206 as the generalized term for the aforementioned “any layer that provides for a temperature difference between surface 1252 and surface 1254.”

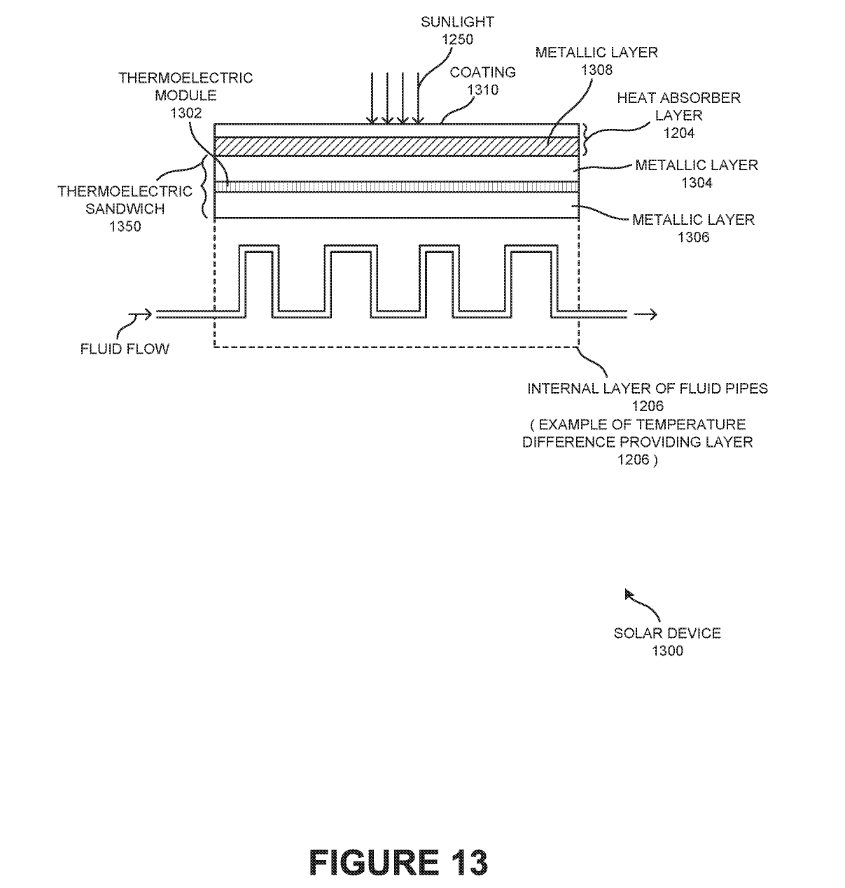

FIG. 13 shows another solar device 1300, according to one or more embodiments. Here, in one or more embodiments, a thermoelectric module 1302 (e.g., thermoelectric module 970, embodiments of FIGS. 3-8) may be sandwiched between two metallic layers, viz. metallic layer 1304 and metallic layer 1306, with thermoelectric module 1302 contacting both metallic layer 1304 and metallic layer 1306; FIG. 13 shows thermoelectric sandwich 1350 as including thermoelectric module 1302, metallic layer 1304 and metallic layer 1306. Examples of each of metallic layer 1304 and metallic layer 1306 include Copper and Aluminum. Other materials are within the scope of the exemplary embodiments discussed herein. It should be noted that metallic layer 1304 and metallic layer 1306 may be of the same material or of different materials.

Also, in one or more embodiments, it should be noted that thermoelectric sandwich 1350 may introduced right behind heat absorber layer 1204 and in contact therewith, as shown in FIG. 13. In other words, metallic layer 1304 may contact the metallic layer (e.g., metallic layer 1308; FIG. 13 also shows coating 1310 (e.g., TiNOX discussed above) on top of metallic layer 1308; both coating 1310 and metallic layer 1308 may form part or whole of heat absorber layer 1204) of heat absorber layer 1204. In one or more embodiments, solar device 1300 may be similar to solar device 1200, except for substitution of thermoelectric module 1202 with thermoelectric sandwich 1350. In one or more embodiments, the specific configuration of solar device 1300 disclosed in FIG. 13 with thermoelectric sandwich 1350 may warrant only minimal changes to the existing manufacturing process thereof. In certain aspects, in one or more embodiments, thermoelectric sandwich 1350 may be viewed as a thermoelectric module analogous to thermoelectric module 1202.

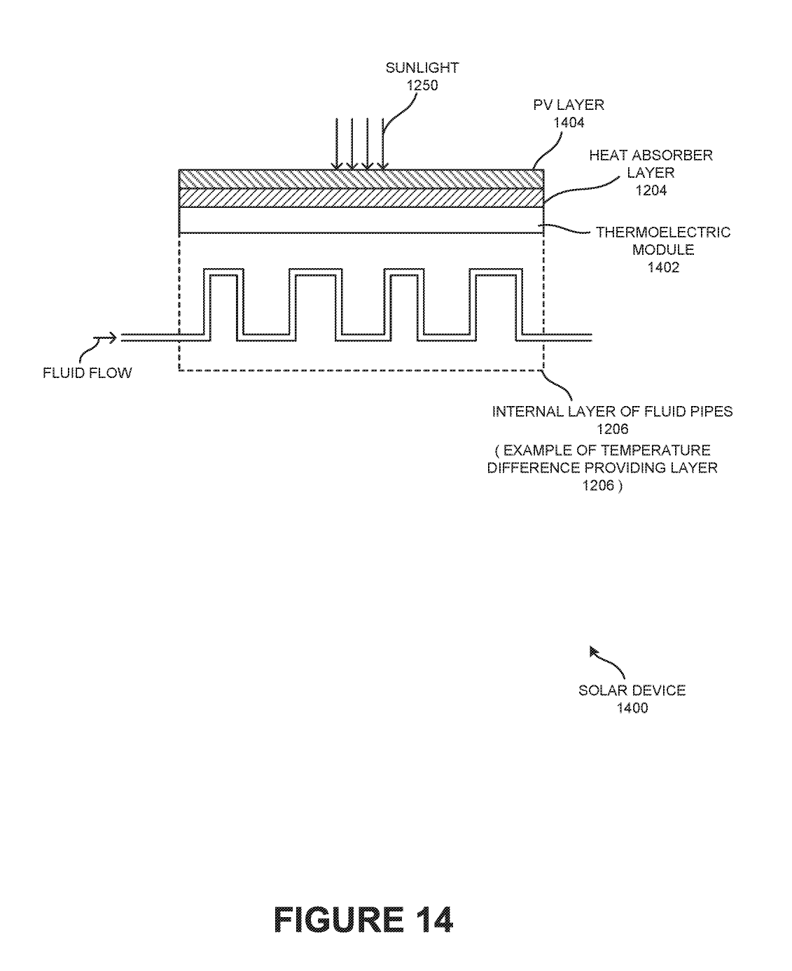

FIG. 14 shows yet another solar device 1400, according to one or more embodiments. In one or more embodiments, solar device 1400 may include a photovoltaic (PV) layer 1404 directly on top of heat absorber layer 1204 and in contact therewith. In one or more embodiments, a thermoelectric module 1402 analogous to thermoelectric module 1202 or thermoelectric module 1302 part of thermoelectric sandwich 1350 may be directly coupled to (e.g., placed right below) heat absorber layer 1204 and in contact therewith (refer to the embodiments of FIGS. 12-13).

When sunlight 1250 is incident on PV layer 1404, a large portion of said sunlight 1250 may be absorbed by a semiconductor material of PV layer 1404, thereby effecting a transfer of energy from photons to electrons. The flow of these electrons may constitute an electric current. This electric current may be utilized to power a grid or another element. It is obvious that PV layer 1404 may include solar cells made of semiconductor material such as Silicon and Cadmium Telluride. Other materials are within the scope of the exemplary embodiments discussed herein.

The working of photovoltaic cells is well known to one skilled in the art. Detailed discussion thereof is, therefore, skipped for the sake of convenience and brevity. In one or more embodiments, heat absorber layer 1204 placed below PV layer 1404 may provide for cooling of solar cells within PV layer 1404. In one or more embodiments, heat absorber layer 1204 may then be able to leverage energy from PV layer 1404 that is unrecoverable without the presence of heat absorber layer 1204 within solar device 1400.

Again, it should be understood that solar device 1400 may be analogous to solar device 1300 and solar device 1200, except for the inclusion of PV layer 1404 on top of heat absorber layer 1204. Exemplary embodiments disclosed in FIG. 14 may not only enable solar device 1400 to produce electricity (because of PV layer 1404) but also to leverage a temperature difference across surfaces of thermoelectric module 1402 to simultaneously heat internal layer of fluid pipes 1206 (e.g., water, air, fluid).

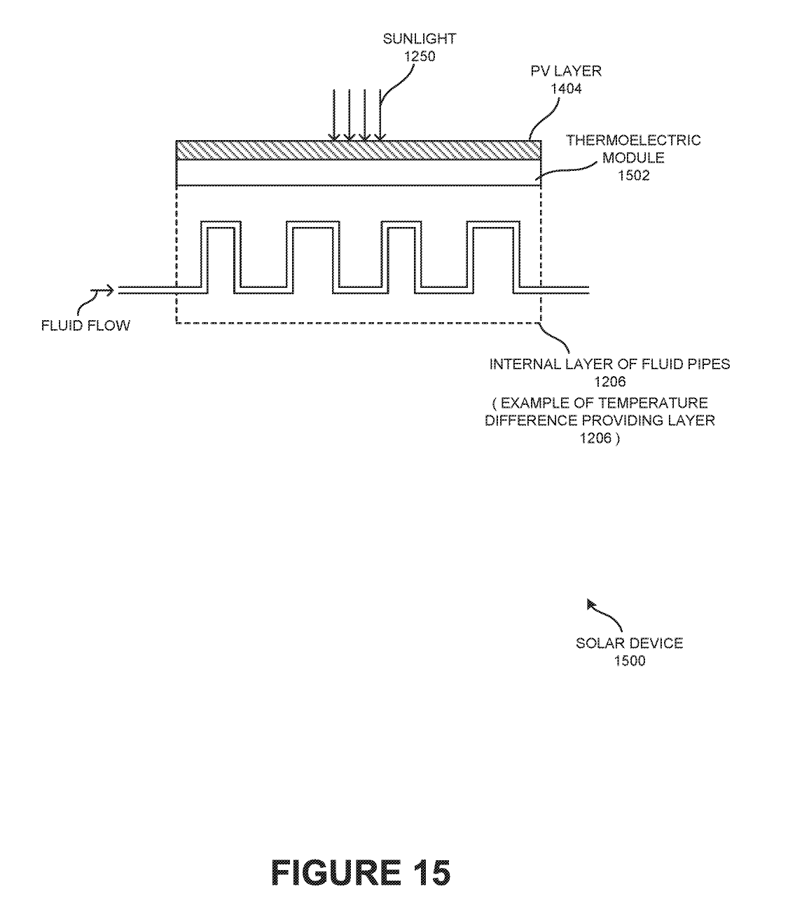

It should be noted that any combination of a thermoelectric module (e.g., thermoelectric module 1202, thermoelectric sandwich 1350, thermoelectric module 1402) with PV layer 1404 and heat absorber layer 1204 may be envisioned according to the application toward which a corresponding solar device (e.g., solar device 1200, solar device 1300, solar device 1400) is targeted. FIG. 15 shows still yet another solar device 1500, according to one or more embodiments. Here, PV layer 1404 may directly be on top of a thermoelectric module 1502 (e.g., thermoelectric module 1202, thermoelectric sandwich 1350) and in contact therewith. Again, in one or more embodiments, sunlight 1250 incident on PV layer 1404 may be leveraged to generate electricity; temperature difference across surfaces of thermoelectric module 1402 (e.g., surface 1252 and surface 1254 of thermoelectric module 1202, metallic layer 1304 and metallic layer 1306 of thermoelectric sandwich 1350) may be leveraged to simultaneously heat internal layer of fluid pipes 1206.

While focused solar absorption through heat absorber layer 1204 is missing in solar device 1500 of FIG. 15, the advantages of thermoelectric module 970 and the embodiments thereof in FIGS. 3-8 may still be realized in solar device 1500, as in solar device 1200, solar device 1300 and solar device 1400. Example applications in which solar device 1200, solar device 1300, solar device 1400 and/or solar device 1500 may be employed include but are not limited to solar air cooling (temperatures of heat energy required may range from 160-180° C.), solar desalination (temperatures of heat energy required may range from 120-140° C.), solar dehydration (temperatures of heat energy required may range from 120-140° C.) and solar process heating (temperatures of heat energy required may range from 100-200° C.).

Thus, in one or more embodiments, thermoelectric module 970 and the embodiments thereof in FIGS. 3-8 may find use in 24×7 operation of solar devices (e.g., solar device 1200, solar device 1300, solar device 1400, solar device 1500) with continuous electric power and solar thermal power generation. The thin-film nature of elements of thermoelectric module 970 and the embodiments thereof in FIGS. 3-8 may lead to enhancements of existing solar devices (e.g., into solar device 1200, solar device 1300, solar device 1400 and/or solar device 1500) without changes in looks and/or outward physical appearances thereof; the aforementioned existing solar devices may otherwise be equivalent to solar device 1200, solar device 1300, solar device 1400 and/or solar device 1500. In one or more embodiments, the aforementioned enhancements may provide for increased (e.g., three to fourfold) solar thermal power and/or electrical power output compared to these existing solar devices.

In one or more embodiments, thermoelectric module 970 and embodiments thereof in FIGS. 3-8 may provide for the first cost-effective solar, thermoelectric and solar-thermal panels based on thin-film thermoelectrics. In one or more embodiments, the thin-film basis may provide for negligible increase in weight of the abovementioned enhanced solar devices due to addition of thermoelectric module 970 and embodiments thereof in FIGS. 3-8.

It should be noted that solar device 1200, solar device 1300, solar device 1400 and solar device 1500 may be examples of hybrid solar/thermoelectric and hybrid solar thermal/thermoelectric devices. To generalize, exemplary embodiments may relate to hybrid solar and solar thermal devices with embedded thermoelectric module (e.g., thermoelectric module 1202, thermoelectric sandwich 1350, thermoelectric module 1402, thermoelectric module 1502).

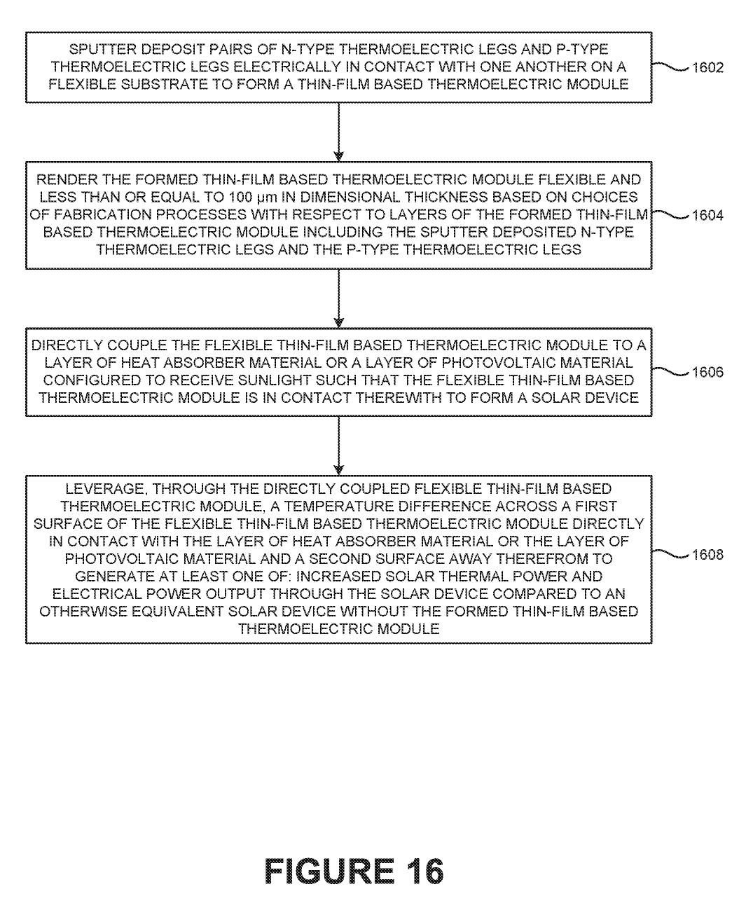

FIG. 16 shows a process flow diagram detailing the operations involved in realizing a solar device (e.g., solar device 1200, solar device 1300, solar device 1400, solar device 1500), according to one or more embodiments. In one or more embodiments, operation 1602 may involve sputter depositing pairs of N-type thermoelectric legs (e.g., N-type thermoelectric legs 602_{1-P}) and P-type thermoelectric legs (e.g., P-type thermoelectric legs 604_{1-P}) electrically in contact with one another on a flexible substrate (e.g., substrate 350) to form a thin-film based thermoelectric module (e.g., thermoelectric module 970 and the embodiments of FIGS. 3-8, thermoelectric module 1202, thermoelectric sandwich 1350, thermoelectric module 1402, thermoelectric module 1502).

In one or more embodiments, the flexible substrate may be an Al foil, a sheet of paper, teflon, plastic, polyimide, a single-sided metal clad laminate, or a double-sided metal clad laminate. In one or more embodiments, operation 1604 may involve rendering the formed thin-film based thermoelectric module flexible and less than or equal to 100 μm in dimensional thickness based on choices of fabrication processes with respect to layers of the formed thin-film based thermoelectric module including the sputter deposited N-type thermoelectric legs and the P-type thermoelectric legs. In one or more embodiments, operation 1606 may involve directly coupling the flexible thin-film based thermoelectric module to a layer of heat absorber material (e.g., heat absorber layer 1204) or a layer of photovoltaic material (e.g., PV layer 1404) configured to receive sunlight (e.g., sunlight 1250) such that the flexible thin-film based thermoelectric module is in contact therewith to form the solar device.

In one or more embodiments, operation 1608 may then involve leveraging, through the directly coupled flexible thin-film based thermoelectric module, a temperature difference across a first surface (e.g., surface 1252, metallic layer 1304) of the flexible thin-film based thermoelectric module directly in contact with the layer of heat absorber material or the layer of photovoltaic material and a second surface (e.g., surface 1254, metallic layer 1306) away therefrom to generate increased solar thermal power and/or electrical power output through the solar device compared to an otherwise equivalent solar device without the formed thin-film based thermoelectric module.

Although the present embodiments have been described with reference to specific example embodiments, it will be evident that various modifications and changes may be made to these embodiments without departing from the broader spirit and scope of the various embodiments. Accordingly, the specification and drawings are to be regarded in an illustrative rather than a restrictive sense.

What is claimed is:

1. A method of a solar device comprising:
sputter depositing pairs of N-type thermoelectric legs and P-type thermoelectric legs electrically in contact with one another on a flexible substrate to form a thin-film based thermoelectric module, the flexible substrate being one of: aluminum (Al) foil, a sheet of paper, teflon, plastic, polyimide, a single-sided metal clad laminate, and a double-sided metal clad laminate;
rendering the formed thin-film based thermoelectric module flexible and less than or equal to 100 μm in dimensional thickness based on choices of fabrication processes with respect to layers of the formed thin-film based thermoelectric module including the sputter deposited N-type thermoelectric legs and the P-type thermoelectric legs;
directly coupling the flexible thin-film based thermoelectric module to one of: a layer of heat absorber material and a layer of photovoltaic material configured to receive sunlight such that the flexible thin-film based thermoelectric module is in contact therewith to form the solar device; and
leveraging, through the directly coupled flexible thin-film based thermoelectric module, a temperature difference across a first surface of the flexible thin-film based thermoelectric module directly in contact with the one of: the layer of heat absorber material and the layer of photovoltaic material and a second surface away therefrom to generate at least one of: increased solar thermal power and electrical power output through the solar device compared to an otherwise equivalent solar device without the formed thin-film based thermoelectric module.

2. The method of claim 1, further comprising:
sandwiching the formed flexible thin-film based thermoelectric module between a first metallic layer and a second metallic layer to form a thermoelectric sandwich; and
directly coupling the formed thermoelectric sandwich as the flexible thin-film based thermoelectric module to the one of: the layer of heat absorber material and the layer of photovoltaic material.

3. The method of claim 1, wherein when the flexible thin-film based thermoelectric module is directly coupled to the layer of heat absorber material, the method further comprises:
directly coupling the layer of photovoltaic material configured to receive the sunlight also received by the layer of heat absorber material on top of the layer of heat absorber material.

4. The method of claim 1, wherein forming the thin-film based thermoelectric module comprises utilizing one of: a photomask and a hard mask with patterns corresponding to one of: the N-type thermoelectric legs and the P-type thermoelectric legs to aid the sputter deposition thereof.

5. The method of claim 1, wherein forming the thin-film based thermoelectric module further comprises:
printing and etching a design pattern of metal onto the flexible substrate to form electrically conductive pads, leads and terminals on the flexible substrate;
additionally electrodepositing a seed metal layer comprising at least one of: Chromium (Cr), Nickel (Ni) and Gold (Au) directly on top of the formed electrically conductive pads, the leads and the terminals on the flexible substrate following the printing and etching thereof; and
sputter depositing the N-type thermoelectric legs and the P-type thermoelectric legs directly on top of the electrodeposited seed metal layer.

6. The method of claim 5, further comprising sputter depositing a barrier metal layer comprising one of: Cr, Ni and Au on top of the sputter deposited pairs of the N-type thermoelectric legs and the P-type thermoelectric legs utilizing one of: another photomask and another hard mask to further aid metallization contact therewith.

7. The method of claim 6, further comprising depositing conductive interconnects on top of the sputter deposited barrier metal layer utilizing yet another hard mask to assist selective application thereof.

8. A method of a solar device comprising:
forming a flexible thin-film based thermoelectric module of less than or equal to 100 μm in dimensional thickness on a flexible substrate based on choices of fabrication processes and materials with respect to layers of the formed thin-film based thermoelectric module, the flexible substrate being one of: an Al foil, a sheet of paper, teflon, plastic, polyimide, a single-sided metal clad laminate, and a double-sided metal clad laminate;
directly coupling the flexible thin-film based thermoelectric module to one of: a layer of heat absorber material and a layer of photovoltaic material configured to receive sunlight such that the flexible thin-film based thermoelectric module is in contact therewith to form the solar device; and
leveraging, through the directly coupled flexible thin-film based thermoelectric module, a temperature difference across a first surface of the flexible thin-film based thermoelectric module directly in contact with the one of: the layer of heat absorber material and the layer of photovoltaic material and a second surface away therefrom to generate at least one of: increased solar thermal power and electrical power output through the solar device compared to an otherwise equivalent solar device without the formed thin-film based thermoelectric module.

9. The method of claim 8, further comprising:
sandwiching the formed flexible thin-film based thermoelectric module between a first metallic layer and a second metallic layer to form a thermoelectric sandwich; and
directly coupling the formed thermoelectric sandwich as the flexible thin-film based thermoelectric module to the one of: the layer of heat absorber material and the layer of photovoltaic material.

10. The method of claim 8, wherein when the flexible thin-film based thermoelectric module is directly coupled to the layer of heat absorber material, the method further comprises:
directly coupling the layer of photovoltaic material configured to receive the sunlight also received by the layer of heat absorber material on top of the layer of heat absorber material.

11. The method of claim 8, wherein forming the flexible thin-film based thermoelectric module further comprises:
sputter depositing pairs of N-type thermoelectric legs and P-type thermoelectric legs electrically in contact with one another on the flexible substrate; and
utilizing one of: a photomask and a hard mask with patterns corresponding to one of: the N-type thermoelectric legs and the P-type thermoelectric legs to aid the sputter deposition thereof.

12. The method of claim 11, wherein forming the flexible thin-film based thermoelectric module further comprises:
printing and etching a design pattern of metal onto the flexible substrate to form electrically conductive pads, leads and terminals on the flexible substrate;
additionally electrodepositing a seed metal layer comprising at least one of: Cr, Ni and Au directly on top of the formed electrically conductive pads, the leads and the terminals on the flexible substrate following the printing and etching thereof; and
sputter depositing the N-type thermoelectric legs and the P-type thermoelectric legs directly on top of the electrodeposited seed metal layer.

13. The method of claim 12, further comprising sputter depositing a barrier metal layer comprising one of: Cr, Ni and Au on top of the sputter deposited pairs of the N-type thermoelectric legs and the P-type thermoelectric legs utilizing one of: another photomask and another hard mask to further aid metallization contact therewith.

14. The method of claim 13, further comprising depositing conductive interconnects on top of the sputter deposited barrier metal layer utilizing yet another hard mask to assist selective application thereof.

15. A method of a solar device comprising:
forming a flexible thin-film based thermoelectric module of less than or equal to 100 μm in dimensional thickness on a flexible substrate based on choices of fabrication processes and materials with respect to layers of the formed thin-film based thermoelectric module, the flexible substrate being one of: an Al foil, a sheet of paper, teflon, plastic, polyimide, a single-sided metal clad laminate, and a double-sided metal clad laminate;
directly coupling the flexible thin-film based thermoelectric module to one of: a layer of heat absorber material and a layer of photovoltaic material configured to receive sunlight such that the flexible thin-film based thermoelectric module is in contact therewith to form the solar device; and
leveraging, through the directly coupled flexible thin-film based thermoelectric module, a temperature difference across a first surface of the flexible thin-film based thermoelectric module directly in contact with the one of: the layer of heat absorber material and the layer of photovoltaic material and a second surface away therefrom to generate at least one of: increased solar thermal power and electrical power output through the solar device compared to an otherwise equivalent solar device without the formed thin-film based thermoelectric module while enabling retention of an outward physical appearance of the otherwise equivalent solar device.

16. The method of claim 15, further comprising:
sandwiching the formed flexible thin-film based thermoelectric module between a first metallic layer and a second metallic layer to form a thermoelectric sandwich; and
directly coupling the formed thermoelectric sandwich as the flexible thin-film based thermoelectric module to the one of: the layer of heat absorber material and the layer of photovoltaic material.

17. The method of claim 15, wherein when the flexible thin-film based thermoelectric module is directly coupled to the layer of heat absorber material, the method further comprises:
directly coupling the layer of photovoltaic material configured to receive the sunlight also received by the layer of heat absorber material on top of the layer of heat absorber material.

18. The method of claim 15, wherein forming the flexible thin-film based thermoelectric module further comprises:
sputter depositing pairs of N-type thermoelectric legs and P-type thermoelectric legs electrically in contact with one another on the flexible substrate; and
utilizing one of: a photomask and a hard mask with patterns corresponding to one of: the N-type thermoelectric legs and the P-type thermoelectric legs to aid the sputter deposition thereof.

19. The method of claim 18, wherein forming the flexible thin-film based thermoelectric module further comprises:
printing and etching a design pattern of metal onto the flexible substrate to form electrically conductive pads, leads and terminals on the flexible substrate;
additionally electrodepositing a seed metal layer comprising at least one of: Cr, Ni and Au directly on top of the formed electrically conductive pads, the leads and the terminals on the flexible substrate following the printing and etching thereof; and
sputter depositing the N-type thermoelectric legs and the P-type thermoelectric legs directly on top of the electrodeposited seed metal layer.

20. The method of claim 19, further comprising sputter depositing a barrier metal layer comprising one of: Cr, Ni and Au on top of the sputter deposited pairs of the N-type thermoelectric legs and the P-type thermoelectric legs utilizing one of: another photomask and another hard mask to further aid metallization contact therewith.
